(19) United States
(12) Patent Application Publication
(10) Pub. No.: US 2009/0102355 A1
(43) Pub. Date: Apr. 23, 2009

(54) DISPLAY ELEMENT

(76) Inventors: Christopher J. Winscom, Cambridgeshire (GB); Nicholas I. Phippen, Buckinghamshire (GB)

Correspondence Address: EASTMAN KODAK COMPANY;PATENT LEGAL STAFF, 343 STATE STREET, ROCHESTER, NY, 14650-2201, US

(21) Appl. No.: 12/066,147

(22) PCT Filed: Aug. 3, 2006
(86) PCT No.: PCT/GB2006/002880

§ 371 Date: Jul. 18, 2008

(30) Foreign Application Priority Data
Sep. 10, 2005 (GB) 0518512.9

(51) Int. Cl. H01J 1/62

(52) U.S. Cl. 313/503

(57) ABSTRACT

The invention provides an element for a colour electroluminescent display for displaying multicoloured information, each element comprising at least two sub elements. One sub element comprises an electroluminescent material and a fluorescent material and a further sub element comprises the electroluminescent material and a filter material to select a portion of the electroluminescent emission.

### FIELD OF THE INVENTION

The invention relates to the field of colour displays, in particular to electro luminescent displays and components for use in industries using electronic displays.

### BACKGROUND OF THE INVENTION

The human eye can assimilate three colours, red, green and blue, to represent all perceivable colours. To display colour information it is necessary to generate red, green and blue light of variable amounts to produce a representation of colour space.

One approach to achieving this is to provide each display element or pixel with three sub elements each of which emit red, green or blue light. In this way any colour may be generated at any point in the image and full colour video image display is possible. Although it is electrically efficient to provide sub elements which emit only light of the colour primary required this can cause significant complexity in the display manufacturing process. For this reason other approaches have been developed which, whilst less efficient, offer manufacturing simplification and result in cost savings.

Another approach to the display of multicolour information, typically of use in displaying static images or information for simple animations, is to select primary colours which exactly match the desired display colour and deposit the electroluminescent material only where it is needed to display the required image or where animated features are required to light up. It is not possible to display any colour at any point on the display but this is not necessary, for example in some advertising or signage applications. One benefit of selecting optimal primaries is that exact colour matches, for example of company logos, can be achieved. Some signage applications only require two primaries to be used to display all the coloured information needed.

Conventional powder phosphors for AC electroluminescent excitation, typically copper doped zinc sulphide, emit most efficiently in a green/blue (GB) wavelength region. It is conventional to add either a second phosphor or fluorescer (yellow or orange) to achieve a broad white emission from which the three primary colours can be filtered. This is known as “colour by white” (CBW). CBW is inherently inefficient because to produce each primary colour the other two must be filtered out. In the case of AC Electroluminescent (ACEL) displays the white is often deficient in red wavelengths so that the derived red primary light is weak. Converting the blue emission directly to red light using organic materials requires a fluorescer with a large Stokes' shift. This is typically an inefficient conversion process.

Another problem that is seen in colour emissive displays which derive the three colour primaries from two or more luminescent materials is that of differential aging. This causes an undesired colour shift and occurs when one of the material ages at a different rate from the others.

Ifire Technology Inc use a system, known as Color By Blue™. They use a neutral filter to reduce the blue output, see WO 2004/036961. This system has been used for Thin Film Electroluminescence.

Other electroluminescent sources could include thin film devices, for example organic light emitting diode (OLED) and polymer light emitting diode (PLED) devices and in particular, phosphorescent OLED (PHOLED™) devices. For full colour display proposes the advantageous efficiency of PHOLED™ devices is marred by the inability to produce a suitable pure blue PHOLED. However high-output PHOLEDs emitting at slightly longer wavelengths in the blue green region of the spectrum are well documented, see for example U.S. Pat. No. 6,916,554.

### PROBLEM TO BE SOLVED BY THE INVENTION

The invention aims to provide efficient full colour from an electroluminescent source. Full colour comprises at least three primaries, typically red, green and blue, but the invention is not so limited. The invention is equally applicable to four primaries such as RGB+White or RGB+Cyan

Current products using the CBW approach are inefficient. Typical radiance outputs, measured in W/sr/m², can be less than 10% of the original optical emission before filtering.

Commercially available organic dyes when used with phosphors would typically have poor UV stability and chromaticity position.

### SUMMARY OF THE INVENTION

According to the present invention there is provided an element for a colour electroluminescent display for displaying multicoloured information, each element comprising at least two sub elements, one sub element comprising an electroluminescent material and a fluorescent material and a further sub element comprising the electroluminescent material and a filter material to select a portion of the electroluminescent emission, and means for applying electrical excitation to the electroluminescent material of each sub element to produce the electroluminescent emission.

Preferred embodiments of the invention comprise filter arrays incorporating dyes formed from photographic couplers.

Preferably the display element is flexible.

### ADVANTAGEOUS EFFECT OF THE INVENTION

The present invention achieves greater efficiency than the known prior art. In one embodiment in which a single phosphor is used as the electroluminescent material the display does not suffer differential aging as it would if a mixture of electroluminescent phosphors fluorescer were used.

Photographic coupler dyes have greater stability than dyes used previously in the prior art. A better colour balance lifetime is thus achieved.

The invention as disclosed and claimed delivers a European Broadcast Union (EBU) colour gamut required for display at greatly improved efficiencies.

The invention provides an efficient low cost colour display. The display is light leading to low installation and delivery costs. Furthermore the present invention is easy to fabricate. Preferred embodiments of the display are conformable and may be bent.

When used in conjunction with green/blue PHOLED™ light sources to produce a full-colour pixellated display, the invention would allow each OLED pixel to be identical, so that OLED fabrication would require fewer material deposition steps and only a single mask, thus malting it more economical.

### BRIEF DESCRIPTION OF THE DRAWINGS

The invention will now be described with reference to the accompanying drawings in which:

FIG. 1 is a schematic view of the layer structure of an active matrix colour by green/blue (GB) pixellated display;

FIG. 2 is a schematic view of the cross section of a basic embodiment of an optically imaged filter array; and

FIG. 3 is a diagram illustrating the key parameters characterising an ideal filter.

### DETAILED DESCRIPTION OF THE INVENTION

There are two drive types for XY matrix full colour displays: the passive matrix method and the active matrix method.

In the passive matrix (or multiplex drive) method the X pixels of each Y scan line are addressed during a given dwell time and the full frame of “n” Y lines is scanned with a low ratio duty cycle of no more than 1/n. When the electro luminescent element exhibits a threshold “on” condition it offers the advantage of low cost backplane simplicity.

In the active matrix method each (X,Y) pixel is driven by its own dedicated active device such as a thin film transistor (TFT). Active matrix addressing is preferred where it is important to accommodate low efficiency electroluminescers because it allows a high ratio duty cycle approaching 100%.

The invention will be described with reference to the active matrix display. The active matrix embodiment is preferred since there is no cross talk involved. The active matrix embodiment also gives more control of the display.

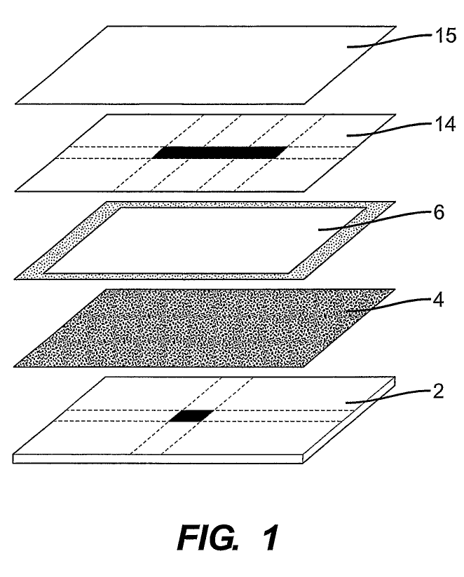

FIG. 1 is a schematic view of the layer structure of an active matrix colour by green/blue (GB) pixellated display.

In the embodiment of the invention described below the electroluminescent material comprises particles of at least one phosphor. It will be understood that the invention is not limited to this embodiment and that any suitable electroluminescent material can be substituted for the particles of phosphor.

A support layer 2 is provided with a pixellated conductor and XY addressed drivers. The layer may be plastic though this is not essential to the invention. Preferably the support layer is flexible as this is advantageous. A flexible support can be bent or conformed to a desired shape and does not shatter. However the invention is not limited to the support layer being flexible. A layer 4 comprising at least one phosphor is provided above the support layer 2. The phosphor is provided in particle form within a dielectric binder. In one embodiment of the invention the layer 4 comprises only a single phosphor. However the layer may comprise a mixture of phosphors. The phosphor particles are preferably of such a size that the layer 4 may be coated onto the support layer 2. A suitable size for the particles thus lies in the range of 0.1-50 microns. Preferably the size ranges from 0.3-30 microns. Even more preferably the range is within 0.3-3 microns.

Provided above the layer 4 is a transparent conductive plane 6. The material of the plane may be inorganic, e.g. ITO, organic, e.g. PEDOT/PSS, or metallic.

A colour conversion array 14 is provided above the conductive plane 6. The colour conversion array comprises a colour filter array and a red fluorescer layer 8. A UV filter overcoat 15 is provided above the array 14.

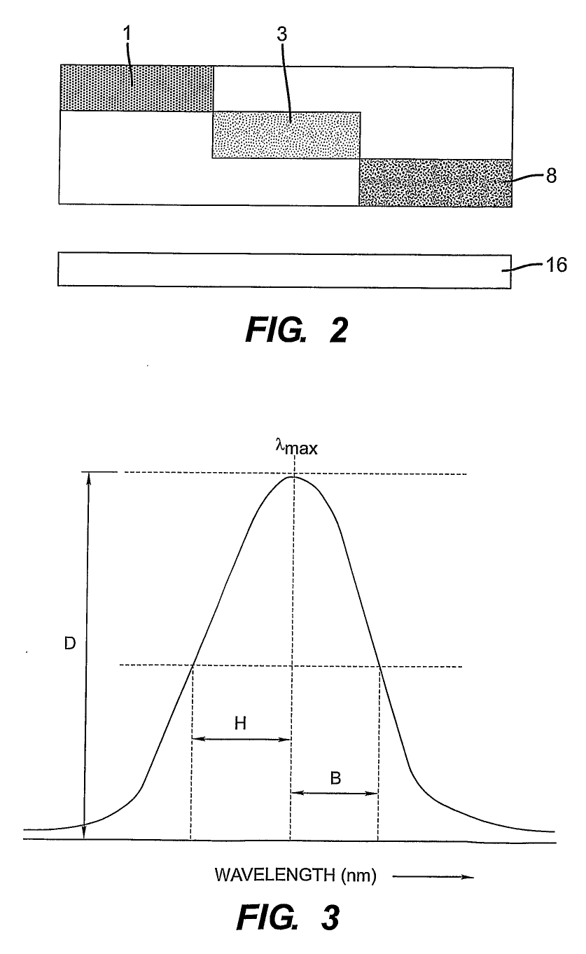

FIG. 2 is a schematic view of a basic embodiment of an optically imaged filter array, together with a lamp assembly 16 and the red fluorescer layer 8. The filter array may comprise a discontinuous blue pass filter 1, a discontinuous green pass filter 3 and a discontinuous red pass filter (not shown). The red pass filter is not essential to the invention but is advantageous in practical embodiments.

The display element comprises at least three sub elements. Each sub element comprises an electroluminescent material and at least one of the red fluorescer, blue pass filter or green pass filter.

For the purposes of illustration the filters and the electroluminescent material are shown in different, discrete, planes. However it should be understood that the filters are not limited to discrete layers but may lie homogenously in a single plane. Furthermore the red fluorescer layer 8 may also be homogenous with at least one of the filter layers as well as in a different plane as illustrated. The relative positions of the layers are not limited to those illustrated, either to each other, or to the lamp assembly 16.

The red fluorescer, blue pass filter and green pass filter may be arranged imagewise in a pictorial representation. It is equally possible that the red fluorescer, blue pass filter and green pass filter are arranged in a geometric pattern.

Preferably the filter array incorporates dyes formed from photographic couplers. Photographic dyes are typically non-fluorescent highly absorptive dyes and have many advantages for fabrication of such arrays over other dye classes. They can be patterned imagewise on flexible substrates by the photographic process with high spatial precision. In this case, they are formed in dispersed hydrophobic oily droplets in hydrophilic polymers like gelatin. The oxygen barrier properties of gelatin (or similar polymer), the additional incorporation of stabilisers in the oil droplets and the fact that the lowest excited singlet states of the dyes are extremely short-lived (sub pS), combine to afford good protection against photochemical decomposition. Consequently, photographic dyes impart greater stability than dyes used in filters in the prior art. Finally, the different classes of photographic dyes produce absorptions throughout the visible region, lending themselves to the design of filter arrays affording versatile colour management.

The filters may incorporate one or more non-fluorescent azamethine dyes derived from any photographic coupler class, e.g. β-ketocarboxamides, pyrazolones, pyrazolotriazoles, phenols and naphthols. The filter may also comprise one or more fluorescent dyes of any class, including those used in dye lasers, e.g. coumarins, porphyrin, naphthalimides, dicyanomethylenes, oxazines or carbocyanines. It will be understood by those skilled in the art that these are examples only and any suitable dyes may be used.

The filter array may be formed by any suitable method. For example, and not by way of limitation, the filter may be formed by inkjet printing, screen printing, by gravure, flexo or litho printing. A photoimaging process may form the filter array where two filters and a single fluorescer are developed according to an optical exposure. Other deposition and patterning methods are equally possible.

In accordance with the invention the electroluminescent material emits light in the green/blue region when an electric field is applied. The useful emission is in the range of 400 to 550 nm, having one or more maxima in the range 460 to 530 nm, preferably with a maxima centred around 475 nm as a compromise between ultimately achievable colour gamut and radiance output. To achieve the colour chromaticity coordinates desired the optical emission must be passed through chromatic filters 10.

### EXAMPLE

It is desired to obtain a blue pixel having colour chromaticity coordinates in the range of x<0.2, y<0.2 To achieve this a filter is required which has an absorption peak of 590 nm, hypsochromic half width (HHW)=55 nm, bathochromic half width (BHW)=45 nm and D=1.5 (where D is the decadic absorbance). This filter should have a radiance efficiency of 0.2-0.9, more preferably greater than 0.4 and most preferably greater than 0.7. Here the radiance efficiency is defined as the ratio of the radiance (w/sr/m²) of an idealised reflector with a filter versus the idealised reflector without a filter, using white light.

To achieve a green pixel having colour chromaticity coordinates in the range of x>0.11 and y>0.45 it is necessary to have a filter which has an absorption peak of 430 nm, HHW=55 nm, BHW=45 nm and D=1.6. This filter should have a radiance efficiency of 0.2-0.7, more preferably greater than 0.4 and most preferably greater than 0.6.

To achieve a red pixel the x coordinate must be greater than 0.6. A fluorescent element in the red fluorescer layer emits light having a peak emission of between 600 and 650 nm, HHW=21 and BHW=42. The efficiency of the fluorescent element in the red fluorescer 8 combined with the electroluminescent material should be between 0.2 and 1, preferably greater than 0.5.

Referring again to FIG. 2, the lamp assembly 16 is a parallel plate capacitor device with an inorganic phosphor arranged between the electrodes. Application of an AC voltage across the electrodes generates a changing electric field within the electroluminescent material causing it to emit light. Safe operation usually requires electro luminescent lamps to be powered by an inverter. An inverter is a DC-AC converter, which typically generates 60-115 V AC and frequencies in the region of 400 Hz. The inorganic phosphor between the electrodes is the equivalent of the ACEL phosphor powder in dielectric binder shown in FIG. 1.

The above description is in respect of an active matrix display. It will be understood that the invention may equally be used with a passive matrix display.

The invention has been described with particular reference to the use of phosphors. However, as stated earlier, the invention is not limited to phosphors. Other electroluminescent materials for use with the invention include, but are not limited to, a thin film electroluminescent material, one layer of a multilayer assembly as in an OLED, PHOLED™ or PLED construction or the emissive component of a cold cathode fluorescer tube.

Modelling software has been designed as a convenience aid to design filters in the following way.

The input to the software is the spectral profile of any light source. This may be one that is a standard source eg A, D65 Ref. “Measuring Colour” R. G. W. Hunt, (1991), or has been characterised experimentally, or it may be a simulated hypothetical profile. The profile is folded with the standard CIE x-, y-, and z-colour matching functions and the resultant integrals normalised (i.e so that x+y+z=1). Both the 1931 and 1964 standards are accommodated. The respective normalised x- and y-values are the CIE colour coordinates of the source. Successive filters may then be imposed on the light source characteristics and the new x- and y-colour coordinates of the transmitted light determined in the same way. The individual filters are described by the four parameters shown in FIG. 4. The normally asymmetric profile of a filter comprising a single absorption band is simulated as two Gaussian halves; one to the “bathochromic” side of the maximum at λₘₐₓ, and the other to the “hypsochromic” side. Each side is characterised by a half-width at half-maximum (HWHM), B and W, respectively. D describes the absorbance at lambda max.

Complex filters may be built up cumulatively from several individual profiles of the type shown in FIG. 4, the xy-colour coordinates of the transmitted light being monitored at each stage.

For the purposes of this invention the spectral limits of the useful emission from the electroluminescent material are determined on the one hand by the efficiency with which the green- and blue fundamentals can be recovered by filtration, and on the other by a width which spans a range sufficient to recover both green- and blue fundamentals with optimum gamut. It is best described in the form of a table:

| Phosphor output | Conversion | B &G |
|---|---|---|
| (FWHM limits) | efficiency | colour gamut |
| 450-535 nm | high | acceptable |
| 440-550 nm | medium | better |
| 430-565 nm | low | best |

The colour gamut of CRT displays is determined by the materials used. Within the total CIE colour space, it is generally accepted that the colour space available to CRT displays is roughly triangular within the full CE colour space, and bounded by the xy coordinates (0.14,0.07) for blue, (0.27,0.80) for green and (0.63,0.33) for red.

The invention has been described in detail with reference to preferred embodiments thereof. It will be understood by those skilled in the art that variations and modifications can be effected within the scope of the invention.

1. An element for a colour electroluminescent display for displaying multicoloured information, each element comprising at least two sub elements, one sub element comprising an electroluminescent material and a fluorescent material and a further sub element comprising the electroluminescent material and a filter material to select a portion of the electroluminescent emission, and means for applying electrical excitation to the electroluminescent material of each sub element to produce the electroluminescent emission.

2. An element as claimed in claim 1 wherein the emission of the electroluminescent material is in the green/blue region.

3. An element as claimed in claim 1 wherein the fluorescent material is a red fluorescent material.

4. An element as claimed in claim 1 wherein the element comprises at least one further sub element, the further sub element comprising the electroluminescent material and a filter material to select a different portion of the electroluminescent emission.

5. An element as claimed in claim 4 wherein the electroluminescent material emits in the green/blue region, the fluorescent material is a red fluorescent material and the filter materials are a blue pass filter and a green pass filter.

6. An element as claimed in claim 1 further including a discrete red pass filter array.

7. An element as claimed in claim 1 wherein the electroluminescent material comprises particles of at least one phosphor.

8. An element as claimed in claim 1 wherein the electroluminescent material is a thin film electroluminescent material.

9. An element as claimed in claim 1 wherein the electroluminescent material is one layer of a multilayer assembly as in an OLED, PHOLED™ or PLED construction.

10. An element as claimed in claim 1 wherein the electroluminescent material is the emissive component of a cold cathode fluorescer tube.

11. An element as claimed in claim 1 wherein the emission of the electroluminescent material due to application of electrical excitation has one or more maxima in the range of 460-530 nm.

12. An element as claimed in claim 11 wherein the maxima is centred around 475 nm.

13. An element as claimed in claim 1 wherein the electroluminescent material, the fluorescent material and the filter material are formed in discrete planes.

14. An element as claimed in claim 1 wherein the fluorescent material and the filter material are combined in one plane.

15. An element as claimed in claim 7 wherein the at least one phosphor comprises particles having a dimension of 0.1-50 microns.

16. An element as claimed in claim 15 wherein the particles are within the range of 0.3-3 microns.

17. An element as claimed in claim 1 wherein the element includes a flexible support layer.

18. An element as claimed in claim 1 wherein the filter material incorporates dyes formed from photographic couplers.

19. An element as claimed in claim 1 whereby the fluorescent material and the filter material are arranged imagewise in a pictorial representation.

20. An element as claimed in claim 1 whereby the fluorescent material and the filter material are arranged in a geometric pattern.

21. An electroluminescent display comprising a plurality of elements as claimed in claim 1, each sub element being driven separately.
